(19) United States
(12) Patent Application Publication
(10) Pub. No.: US 2018/0202960 A1
(43) Pub. Date: Jul. 19, 2018

(54) Fet-Type Gas Sensor and Method of Controlling Gas

(71) Applicant: Hitachi, Ltd., Tokyo (JP)

(72) Inventors: Kazuo ONO, Tokyo (JP); Yoshitaka SASAGO, Tokyo (JP)

(21) Appl. No.: 15/869,943

(22) Filed: Jan. 12, 2018

(30) Foreign Application Priority Data
Jan. 17, 2017 (JP) 2017-005526

(51) Int. Cl. G01N 27/28; H03F 3/45; H01L 29/788; G01N 27/414; H01L 29/06; H01L 29/78

(52) U.S. Cl. CPC G01N 27/28; H03F 3/45179; H01L 29/788; H01L 29/7832; H01L 29/0649; G01N 27/4146; G01N 27/4141

(57) ABSTRACT

There is provided a field effect transistor type gas sensor, the gas sensor including a substrate, an oxide film on the substrate, a gate electrode on the oxide film, a body electrode which is disposed on the substrate, a first switch that changes a voltage which is applied to the gate electrode, and a second switch that changes a voltage which is applied to the body electrode. The gate electrode and the first switch are connected with each other through an electrical wire.

### BACKGROUND OF THE INVENTION

### Field of the Invention

The present invention relates to an FET-type gas sensor and a method of controlling a gas sensor.

### Background Art

A gas sensor outputs a signal according to gas concentration in atmosphere, and is used in a gas densitometer, a leakage detection device, or the like which is for preventing explosion of a combustibility gas such as hydrogen or methane, and bad influence on a human body due to a poisonous gas such as nitric oxide, hydrogen sulfide, and carbon monoxide.

For example, from a view of earth environment preservation, in order to suppress the amount of discharge of CO₂ from a vehicle, a development of a fuel cell vehicle (FCV) from which only water is discharged even though a fuel is combusted and of which a fuel is hydrogen is being progressed. Particularly, a hydrogen densitometer for controlling hydrogen concentration during combustion of hydrogen and detecting leakage of hydrogen from a pipe is required to be mounted on the FCV. In addition, a hydrogen detector is also used for a purpose of a nuclear generator. Since it is known that in a case where concentration of hydrogen in air reaches 3.9%, the hydrogen is exploded, a security measure, such as a measure for generating an alert by a hydrogen densitometer before hydrogen reaches the above described explosion limitation concentration is required in the use for detecting leakage of hydrogen. In addition, in order to improve fuel efficiency performance by optimizing hydrogen concentration during combustion, it is necessary to monitor hydrogen concentration for a purpose of a feedback to a combustion condition.

As a method of a gas sensor, several methods such as a contact combustion method, a semiconductor method, and a gas heat conduction method, are known. However, recently, an FET-type gas sensor, which is able to detect a gas of low concentration with high precision and of which low cost, miniaturization, low consumed power are able to be realized by a production with a process using a semiconductor wafer, is being noted. Particularly, the FET-type gas sensor is noted for a purpose of a vehicle, as cyclic siloxane highly-resistant. It is known that the cyclic siloxane is discharged from asphalt or silicon product used in a road pavement to an environment atmosphere and is a cause of a conduction failure of a contact of an electrical product in a high temperature. However, a catalyst activity of the FET-type gas sensor is hardly changed even in cyclic siloxane atmosphere.

It is known that regardless of constant gas concentration, after a switch of an FET is turned on, a drift in which a temporal change of a threshold voltage of each FET occurs is generated in the FET-type gas sensor.

As a technique for resolving the drift of the FET-type gas sensor, JP-A-2014-32194 discloses a method of applying a preparation voltage to a gate electrode of the field effect transistor, and detecting a measurement amount between a source terminal and a drain terminal of the field effect transistor during a detection period right after the application, while applying a detection voltage to the gate electrode in order to resolve a drift caused by a change of a distribution of an electric field in a field effect transistor element of a gas sensitivity.

In addition, JP-A-2014-115125 discloses a method in which a drift caused by an electric charge caught to a sensitivity film or the like is reduced using a device before a data process in an ion sensitivity field effect transistor. In JP-A-2014-115125, since an electric charge accumulated to a floating electrode is drawn out, a substrate voltage is applied so that a gate oxide film voltage is to be sufficiently greater than that of a normal operation.

### SUMMARY OF THE INVENTION

However, in JP-A-2014-32194, in order to change distribution of the electric field in the FET element, two kinds of voltages of preparation voltage and detection voltage are applied to the gate electrode, a distribution change of the electric field in the element by the application to only the gate electrode is disclosed, and descriptions related to a removal of the electric charge accumulated to the oxide film are not considered. Even though the electric charge is removed, in the configuration of JP-A-2014-32194, for the application to only the gate electrode, it is not that only an electron of the upper portion of the oxide film is removed. The inventor of the present application discovered a new problem that it is necessary to remove an electron in a lower portion of an oxide film in order to more efficiently resolve the drift.

In addition, in the case of the ion sensitivity FET disclosed in JP-A-2014-115125, a material corresponding to the gate electrode of the FET-type gas sensor is a liquid. Therefore, it is based on the premise that the drawing out the electric charge is performed only an area between the floating electrode and the substrate, and the drawing out the electric charge from the liquid is not examined. Meanwhile, in the case of the FET-type gas sensor, due to the film thickness of the oxide film, in order to more efficiently draw out the electric charge, it is necessary to draw out the electric charge from the gate electrode.

An object of the present invention is to effectively remove an electric charge accumulated in an FET-type gas sensor to reduce a temporal change of a threshold voltage in an FET.

According to an aspect of the present invention, there is provided a gas sensor that is a field effect transistor type, the gas sensor including a substrate, an oxide film on the substrate, a gate electrode on the oxide film, a body electrode which is disposed on the substrate, a first switch that changes a voltage which is applied to the gate electrode, and a second switch that changes a voltage which is applied to the body electrode. The gate electrode and the first switch are connected with each other through an electrical wire.

According to the present invention, it is possible to efficiently remove an electric charge accumulated in the FET-type gas sensor by switching the voltage applied to the gate electrode and the voltage applied to the body electrode. For example, it is possible to efficiently remove both of electric charges accumulated in an upper portion and a lower portion of the oxide film. Asa result, it is possible to reduce a temporal change of a threshold voltage in the FET-type gas sensor.

### BRIEF DESCRIPTION OF THE DRAWINGS

FIGS. 1A and 1B are sectional views of a reference FET and a sensor FET.

FIG. 2 is a graph illustrating a comparison of IDS-VGS characteristics of the reference FET and the sensor FET.

FIGS. 3A and 3B are diagrams illustrating a temporal change of a gate-source voltage.

FIG. 4 is a diagram illustrating an electric charge accumulated in an FET.

FIGS. 5A and 5B are diagrams illustrating a voltage application condition of a measurement phase and a refresh phase.

FIGS. 6A and 6B are diagrams illustrating a circuit configuration which changes a direction of a current flowing to a source electrode and a drain electrode.

FIGS. 7A and 7B are diagrams illustrating an example of a relationship of each of clock waveforms.

FIGS. 8A and 8B are diagrams illustrating an example of a waveform of a gate potential control clock.

FIG. 9 is a diagram illustrating an experiment result of a drift reduction effect.

FIG. 10 is a diagram illustrating an example of the entire system configuration.

FIG. 11 is a diagram illustrating a flow which sets a bias condition.

FIGS. 12A and 12B are sectional views illustrating a sensor chip and a reference chip including a wire layer or a protection layer.

FIG. 13 is a diagram illustrating an example of a dedicated circuit of the sensor FET.

FIG. 14 is a diagram illustrating an example of a dedicated circuit of the reference FET.

### DETAILED DESCRIPTION OF THE INVENTION

Hereinafter, embodiments of the present invention will be described in detail with reference to the accompanying drawings. Note that the same components are denoted by the same reference symbols in principle throughout all drawings for describing the embodiments, and the repetitive description thereof will be omitted.

In the below, an FET-type hydrogen sensor is described as an example of an FET-type gas sensor. However, in the FET-type gas sensor, since various gas detections are possible by a change of a kind of a catalyst metal, the following description is not limited to the hydrogen. In addition, in the below, an N channel type sensor is described as an example, but in a P channel type sensor, since a direction of an application voltage is merely inverted, the P channel type sensor is naturally applicable similarly to the N channel type sensor.

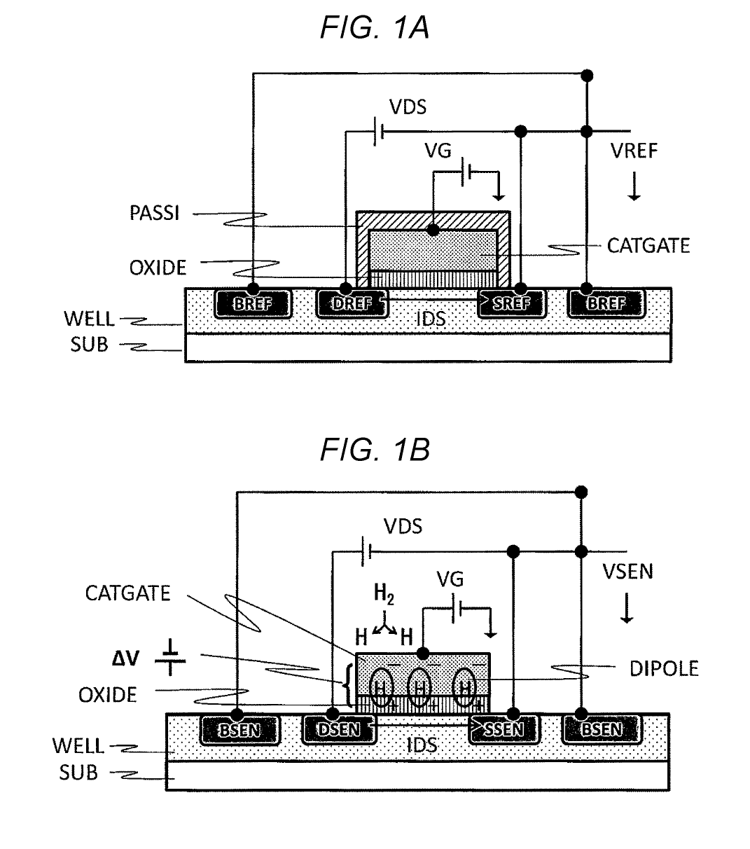

FIGS. 1A and 1B illustrate a hydrogen detection mechanism of an FET-type hydrogen sensor. FIG. 1A is a schematic sectional view illustrating a device of a reference FET. FIG. 1B is a schematic sectional view illustrating a device of a sensor FET.

The device sectional structures of the reference FET and the sensor FET include sizes or film configurations, and are manufactured almost equally. Both of the reference FET and the sensor FET are formed on the same silicon substrate SUB. That is, in FIGS. 1A and 1B, the reference FET and the sensor FET are separately illustrated in FIGS. 1A and 1B, in reality, the silicon substrates are connected with each other, and the reference FET and the sensor FET are adjacent with each other and formed on the same silicon substrate. A well WELL is provided on the silicon substrate, and an FET device is formed in the center of the well WELL.

A catalyst gate electrode CATGATE is a catalyst gate having activity with respect to a hydrogen gas. For example, a laminated film of Pt—Ti—O, Pd film, or the like is considered.

A gate insulation film OXIDE may be formed of SiO₂ similarly to a common FET, but the FET-type hydrogen sensor of the present application is not limited thereto.

As illustrated in FIG. 1A, in the reference FET, the catalyst gate electrode is coated with a detection target barrier film PASSI. The detection target barrier film is formed of a film which does not have permeability of a detection target gas, and for example, in the case of the FET-type hydrogen sensor, a film which does not have hydrogen permeability is selected. Since there is no hydrogen permeability, hydrogen does not reach the catalyst gate electrode, the reference FET does not have hydrogen sensitivity while having a structure the same as that of the sensor FET.

A bias condition of the sensor FET and the reference FET is described. In the sensor FET and the reference FET, the same drain-source voltage VDS is applied to each of a drain terminal and a source terminal. The drain terminal of the reference FET is denoted as DREF, the source terminal of the reference FET is denoted as SREF, the drain terminal of the sensor FET is denoted as DSEN, and the source terminal of the sensor FET is denoted as SSEN. A channel current IDS flows between each of the drain terminals and the source terminals by the application of the drain-source voltage.

In addition, the same gate voltage VG is applied to both of the catalyst gate electrodes. The gate voltage VG is a gate potential based on a ground voltage as a standard, and it is not a gate potential with respect to a source potential.

A well terminal BREF of the reference FET and the source terminal SREF of the reference FET are connected with each other, and a well terminal BSEN of the sensor FET and the source terminal SSEN of the sensor FET are connected with each other, to be operated. Therefore, there is no a potential difference between the well terminal and the source terminal. As a result, a substrate effect is removed. VREF is an output voltage of the reference FET, and VSEN is an output voltage of the sensor FET.

As illustrated in FIG. 1B, the hydrogen gas is decomposed into hydrogen atom or hydrogen ion by a catalyst operation of the catalyst gate electrode of the sensor FET. The hydrogen atom or the hydrogen ion by the decomposition is stored in the catalyst gate electrode, and forms a dipole DIPOLE in the vicinity of an interface with the gate insulation film. A threshold voltage change of ΔV occurs in the sensor FET in comparison with the reference FET, by an action of the dipole, and hydrogen concentration is identified by detecting the threshold voltage change using a detection circuit.

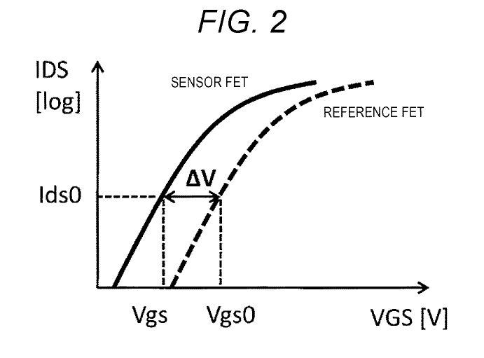

FIG. 2 is a schematic diagram illustrating a comparison of IDS-VGS characteristics of the reference FET and the sensor FET at the time of the hydrogen detection. A line indicates the characteristic of the sensor FET, and a dotted line indicates the characteristic of the reference FET. The application of the same IDS is performed, and thus operation currents are the same. In addition, the application of the same VDS is performed, and thus IDS-VGS curves are same form in the reference FET and the sensor FET. The curve of the sensor FET is shifted to a negative side of the VGS by ΔV caused by the dipole. As described above, the threshold voltage change ΔV is generated as a difference between a gate-source voltage Vgs0 in the reference FET and a gate-source voltage Vgs in the sensor FET. As described above, since the VG is the same in the reference FET and the sensor FET, ΔV is finally detected as a difference between source potentials of both sides, by Vgs, which is a difference between the gate voltage VG and the source voltage VS that is Vgs=VG−VS.

A detection principle of the FET-type hydrogen sensor is described in the above.

It is considered that the hydrogen sensor to which the present invention is applied is installed, for example, in the vicinity of a hydrogen supply port, in the vicinity of an entrance of a hydrogen storage tank, in the vicinity of a supply port of a power device, in an exhaust device or inside a vehicle, in a use of a fuel cell vehicle. In addition, it is considered that the hydrogen sensor to which the present invention is applied is installed in a nuclear reactor building, a control room which is a nuclear reactor assistance building, or the like in a use of a nuclear reactor of a nuclear generator. In addition, the hydrogen sensor may be used in a normal hydrogen detection of a hydrogen infra, and for example, also may be installed in a hydrogen station and in the vicinity of a supply port of a hydrogen dispenser.

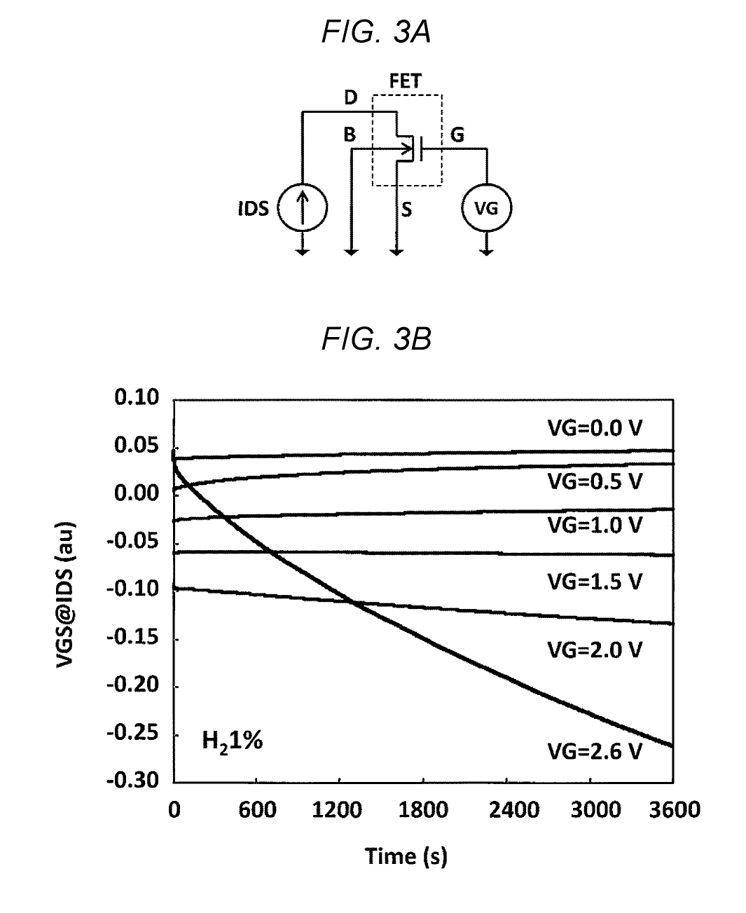

Next, FIGS. 3A and 3B illustrate a result of an experiment in which a temporal change of a gate-source voltage VGS at the time when the sensor FET is left under a constant bias for a long time is measured. FIG. 3A illustrates a bias condition at the measurement time. A current source IDS is connected to a drain electrode D of an FET indicating the sensor FET, a voltage source VG is connected to a gate electrode G of the FET, and a source electrode S and a body electrode B of the FET are grounded.

FIG. 3B is a graph illustrating a temporal change of the VGS under a hydrogen 1% atmosphere. As described above, the change of the VGS is normally caused according to the change of hydrogen concentration. However, it is confirmed that a value of the VGS is temporally changed variously according to a value of the VG in the present experiment result. As long as the hydrogen concentration is not changed from 1%, the VGS which is an output is required to have a constant state, but the change by the VG causes a malfunction as a sensor. In addition, it is known that a direction of a drift is changed according to the value of the VG. That is, in a case where it is satisfied VG=0.0 V, the VGS is temporally increased. In contrast, in a case where VGS is large as VGS=2.6 V is satisfied, the VGS is temporally decreased. In a case where the VG is a medium potential and it is satisfied VG=1.5 V, it is known that the temporal change of the VGS is hardly occurred.

From the experiment result illustrated in FIGS. 3A and 3B, the present inventor considered that the temporal change of the VGS is a change of the VGS which is an output of the sensor FET, which is caused by the following that an electric charge is accumulated in somewhere inside the sensor FET, and the accumulated electric charge changes a threshold voltage VTH of the FET.

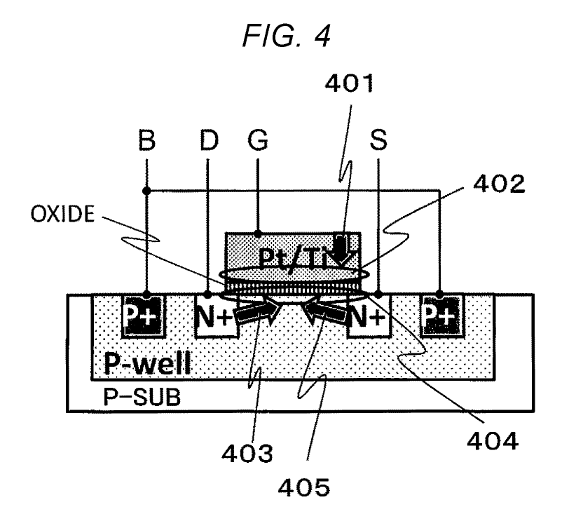

Specifically, a place where an electric charge is accumulated is described with reference to FIG. 4. FIG. 4 is a sectional view of an N channel type sensor FET to which the present example is applied. A sensitivity gate is formed of Pt/Ti, and is connected with the gate electrode G. A voltage source is connected to the gate electrode G by an electrical wire through a first switch 501 which is described later. A P type well P-well is formed on a P type substrate P-SUB, and the body electrode B, the drain electrode D and the source electrode S are formed thereon. The gate insulation film OXIDE is provided between the P type well P-well and the sensitivity gate of Pt/Ti.

Three kinds are considered as electric charges accumulated in a case where the sensor FET is operated. First, an electric charge 402 which is supplied 401 from the gate electrode G and is accumulated in the vicinity of an interface between the Pt/Ti gate and the gate insulation film OXIDE is considered. In addition, an electric charge 404 which is supplied 403 from the drain electrode D and is accumulated in a lower portion of the gate insulation film OXIDE or an interface between the gate insulation film OXIDE and the P type well P-well. Further, an electric charge 404 which is supplied 405 from the source electrode S and is accumulated in the lower portion of the gate insulation film OXIDE or the interface between the gate insulation film OXIDE and the P type well P-well.

In order to more efficiently resolve the drift, the inventor of the present application considered that it is necessary to remove the electric charge 403 of the lower portion of the gate insulation film OXIDE as well as the electric charge 402 of the upper portion of the gate insulation film OXIDE. In the above described JP-A-2014-32194 discloses only the application to the gate electrode G, and it is difficult for the configuration of JP-A-2014-32194 to remove an electric charge of a lower portion of the gate insulation film OXIDE.

Therefore, a configuration in which a plurality of voltages are applied to the body electrode as well as the gate electrode G in order to remove the electric charge of the lower portion of the gate insulation film is provided. For example, two phases of a measurement phase and a refresh phase are provided to the sensor FET and the reference FET, and the voltages applied to each of the gate electrode and the body electrode are changed, to resolve the above described problems. Hereinafter, it is described in detail.

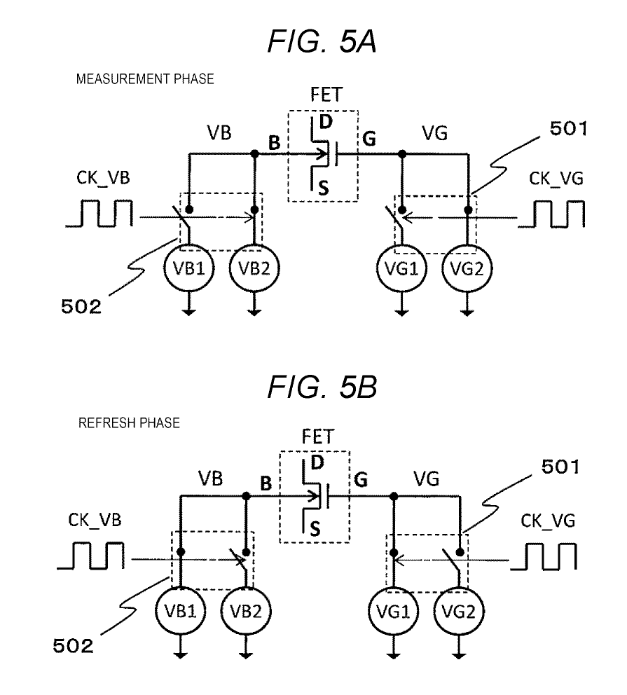

A method of applying two or more kinds of voltages to the gate electrode and the body electrode of the sensor FET and the reference FET is described by using FIGS. 5A and 5B.

FIG. 5A illustrates a voltage application condition at a measurement phase, that is, at the time of a gas concentration measurement. During the measurement, a gate voltage VG2 at the measurement time is selected by a gate potential control clock CK_VG. Simultaneously, a body voltage VB2 at the measurement time is selected by a body potential control clock CK_VB.

FIG. 5B illustrates a voltage application condition during a refresh phase, that is, during a refresh operation for removing the accumulated electric charge. A gate voltage VG1 at the refresh time is selected by a gate potential control clock CK_VG. Simultaneously, a body voltage VB1 at the refresh time is selected by a body potential control clock CK_VB. As described above, in the present example, a first switch 501 for applying a plurality of gate voltages and a second switch 502 for applying a plurality of body voltages are provided. Each of the first switch 501 and the second switch 502 may be configured by one switch, or may be configured by a plurality of switches.

Although not illustrated in FIG. 5B, the gate potential control clock CK_VG and the body potential control clock CK_VB is generated by a clock generation circuit, and a control unit CTRL controls the first switch 501 and the second switch 502 by the gate potential control clock CK_VG and the body potential control clock CK_VB.

The VG1, VG2, VB1 and VB2 are formed by a digital control voltage source. Therefore, an output potential may be controlled with a certain degree in a range of electric power supplied to an analog circuit. In addition, the VG and the VB are provided by the same control voltage source. Therefore, it is possible to perform a high speed operation and change a speed of an output of the control voltage source to a speed the same as the clock, without complying with a control speed of a control circuit or a specification of the control voltage source.

In addition, the gate potential control clock CK_VG and the body potential control clock CK_VB are generated by a control circuit such as a microcomputer. Therefore, a duty ratio or a phase thereof is able to be changed and controlled quite freely. Thus, the gate potential VG and the body potential VB may have a configuration in which the potentials or temporal change patterns thereof are able to be changed quite freely.

As described above, a gas sensor according to the present example includes a substrate SUB, an oxide film OXIDE on the substrate, a gate electrode G on the oxide film, a body electrode B which is disposed on the substrate, a first switch 501 that changes a voltage which is applied to the gate electrode, and a second switch 502 that changes a voltage which is applied to the body electrode. A voltage source is connected to the gate electrode through an electrical wire.

According to the configuration, it is possible to change a voltage applied to the gate electrode or the body electrode, and it is possible to provide two kinds of phases of a measurement phase and a refresh phase. As a result, it is possible to efficiently remove an electric charge accumulated in an FET from the gate electrode, and thus a temporal change of a threshold voltage of the FET is reduced.

In addition, the gas sensor according to the present example includes a voltage source which generates a plurality of voltages, and the first switch 501 switches the connection between the gas sensor and the plurality of voltages VG1 and VG2 which are generated by the voltage source. Therefore, the voltage applied to the gate electrode G is changed. According to the configuration, it is possible to efficiently remove the electric charge accumulated in the gate insulation film OXIDE from the gate electrode G.

Further, the gas sensor according to the present example includes a voltage source which generates a plurality of voltages. The second switch 502 switches the connection between the gas sensor and the plurality of voltages VB1 and VB2 which are generated by the voltage source. Therefore, the voltage applied to the body electrode B is changed. According to the configuration, it is possible to efficiently remove the electric charge accumulated in the lower portion of the gate insulation film OXIDE or the interface between the gate insulation film OXIDE and the substrate P type well from the substrate. In addition, it is possible to change the voltage applied to the gate electrode and the body electrode by switching the connection between the gas sensor and both of the first switch and the second switch. According to the configuration, with respect to various electric charge accumulations, it is possible to entirely remove the electric charge from the gate electrode or the substrate, and it is possible to more efficiently and accurately remove the electric charge. Accordingly, a drift suppression is possible.

In addition, a method in which each of the VG and the VB is provided from individual single voltage source and output potentials thereof are changed by a timely control circuit is also considered. In this case, the gate potential control clock CK_VG and the body potential control clock CK_VB are not necessary.

FIG. 9 is a graph illustrating an experiment comparison of drift amounts between a case where a drift suppression is performed and a case where the drift suppression is not performed in the present example. According to the application of the configuration of the present example, the drift amount of approximately 75% is suppressed. The experiment is performed by an N type FET sensor at a temperature of 113° C., and in the experiment condition, a body potential VB2 of a measurement phase is set as 1.22 V, a gate potential VG2 of the measurement phase is set as 4.88 V, a body potential VB1 of a refresh phase is set as 0 V, and a gate potential VG1 of the refresh phase is set as 5 V. The obtaining effect of suppressing the drift amount by the application of the present invention is also apparent by the experiment like this.

### Modification Example Related to Control of Direction of Current Between Source Electrode and Drain Electrode

In the above, the configuration in which the voltage applied to the gate electrode or the body electrode is changed, and the refresh phase is provided in addition to the measurement phase, to remove the electric charge accumulated in the sensor is described. Hereinafter, a configuration in which a direction of a current flowing to a sensor is changed, and thus an electric charge accumulated in the sensor is more efficiently removed is described. Particularly, a configuration in which an electric charge accumulated in an interface between a lower portion of a gate insulation film and a P type well or a channel formed in the P type well is efficiently removed is described.

The basic configuration is the same as that of FIG. 4, but the following is different.

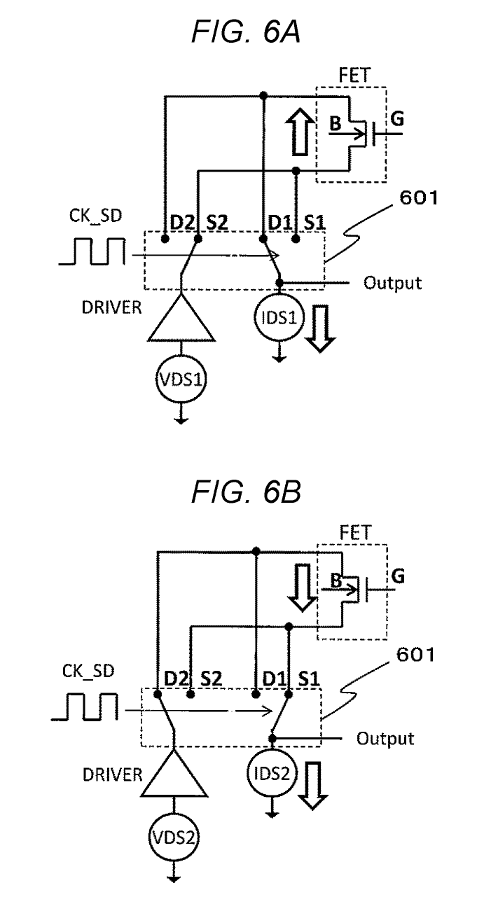

FIGS. 6A and 6B illustrate an example of a mechanism for changing the direction of the current flowing to the FET sensor. FIG. 6A illustrates a circuit configuration of a case where the current flows from the source electrode S to the drain electrode D, and FIG. 6B illustrates a circuit configuration of a case where the current flows from the drain electrode D to the source electrode S.

First, in FIG. 6A, a source drain control clock CK_SD is applied to a source-drain switch 601 by the control unit CTRL so that a current source IDS1 is connected to a first drain terminal D1 and a drive circuit DRIVER which outputs a VDS1 by a voltage source is connected to a second source terminal S2.

Next, in FIG. 6B, the source drain control clock CK_SD is applied to the source-drain switch 601 by the control unit CTRL so that a current source IDS2 which changes a current value to the IDS is connected to a first source terminal S1 and the drive circuit DRIVER which outputs a VDS2 by the voltage source is connected to a second drain terminal D2.

Such a control clock is generated by a clock generation circuit. For example, FIG. 6A illustrates a circuit configuration in a case where the source drain control clock CK_SD=H, and FIG. 6B illustrates a circuit configuration in a case where the source drain control clock CK_SD=L. The source-drain switch 601 may be, for example, configured from two switches. The source-drain switch 601 may connect an H input terminal to an output terminal when a clock input is H, and may connect an L input terminal to the output terminal when the clock input is L. For example, a configuration having a role of a switch for combining a signal of an analog level as it is is considered. In addition, the source-drain switch 601 may be formed by applying a switch the same as the first switch 501 or the second switch 502.

In each of the cases of FIGS. 6A and 6B, a configuration in which an output current of the current source IDS may be changed by a control current source is possible. It is possible to more efficiently remove the accumulated electric charge, and the drift control with high efficiency is possible, by changing the direction of the current flowing to the sensor and the current value. Similarly, it is possible to apply a control voltage source to also the voltage source which generates the VDS.

As described above, in a case of a circuit configuration in which the control voltage source output and the control current source output are connected to the first source terminal S1 and the second drain terminal D2, and the second source terminal S2 and the first drain terminal D1, respectively, while switching, the output voltage VDS and the output current IDS of the case where a current flows from the source electrode to the drain electrode become a VDS1 and an IDS1, respectively, and the output voltage VDS and the output current IDS of the case where a current flows from the drain electrode to the source electrode become a VDS2 and an IDS2, respectively. That is, since a symmetry at the time of a sensor operation is destroyed, in a case where the accumulated electric charge is present in the vicinity of a channel or the vicinity of an interface between the gate oxide film and the P type well, it is possible to more efficiently remove the accumulated electric charge, in comparison with in a case where the same current flows in one direction.

On the other hand, VDS1=VDS2 and IDS1=IDS2 may be set, and in this case, operations of the FET sensor is symmetrical. Thus, it is easy to create a situation in which the occurrence of the accumulation of the electric charge is prevented. A method of setting values of the output voltage VDS and the output current IDS is determined at a test time according to a deviation of a sensor device. Therefore, it is possible to create an FET sensor with high reliability.

As described above, the gas sensor according to the present example includes the source electrode S and the drain electrode D which are disposed on the substrate, the voltage source DRIVER which generates a plurality of voltages, the current source IDS which generates a plurality of currents, and the source-drain switch 601 that changes the direction of the current flowing to the source electrode and the drain electrode. The source-drain switch 601 switches the connection between the first source terminal S1 of the source electrode and the voltage source, the connection between the first drain terminal D1 of the drain electrode and the current source, the connection between the second drain terminal D2 of the drain electrode and the voltage source, and the connection between the second source terminal S2 of the source electrode and the current source. Therefore, the direction of the current flowing to the source electrode and the drain electrode is changed. According to the configuration, it is possible to change the direction of the current flowing to the source electrode and the drain electrode, and it is possible to efficiently remove the electric charge accumulated in the vicinity of the channel formed in the P type well or in the vicinity of the interface between the lower portion of the gate oxide film and the P type well.

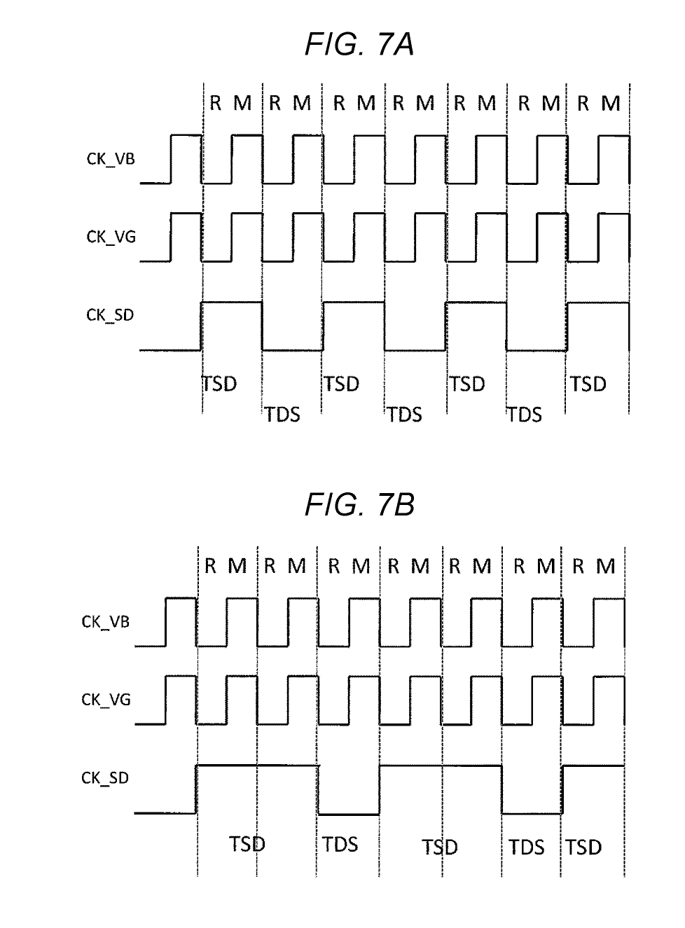

FIGS. 7A and 7B are diagrams illustrating an example of a phase relationship of a body potential control clock CK_VB, a gate potential control clock CK_VG, and a source drain control clock CK_SD. Since they are clock waveforms, each of the voltage levels of the waveforms is changed between 0 V and a power voltage of a circuit. The example is an example in a case where a refresh operation period R and a measurement operation period M are equal to each other.

FIG. 7A illustrates an example in a case where a length of a time TSD in which the current flows from the source electrode to the drain electrode and a length of a time TDS in which the current flows from the drain electrode to the source electrode are equal to each other, in the source drain control clock CK_SD. On the other hand, FIG. 7B illustrates an example in a case where TSD>TDS is set. Even any case, the TDS and the TSD are set so as to have the length of an integer time of one period of the gate potential control clock CK_VG and the body potential control clock CK_VB. As described above, by setting the time in which the current flows, it is possible to perform the measurement phase and the refresh phase by the same number at the time of the direction of the IDS. Therefore, it is expected that the drift is suppressed with higher precision.

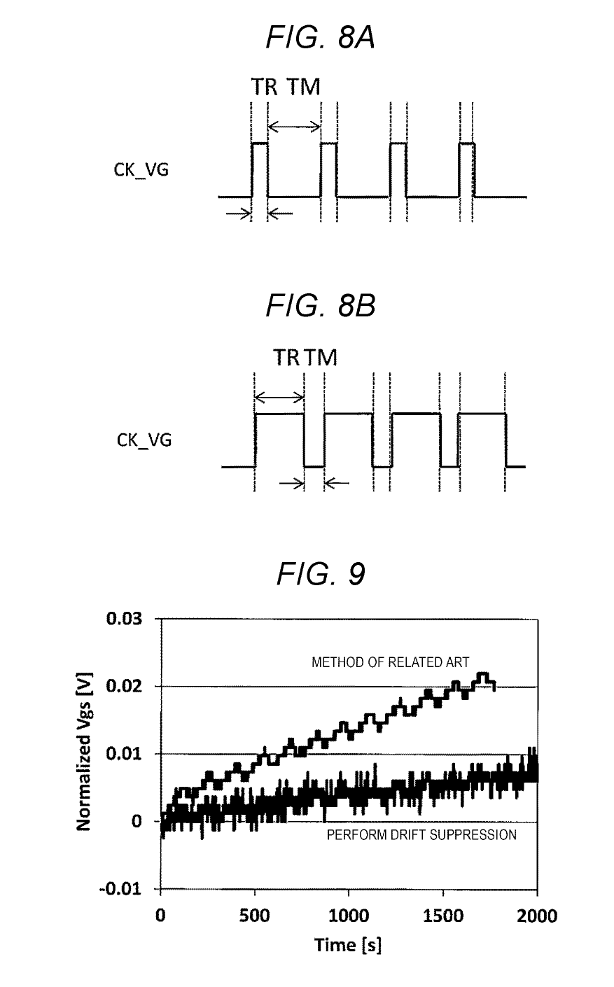

FIGS. 8A and 8B illustrate waveform examples of the gate potential control clock CK_VG. FIG. 8A illustrates a waveform example in a case where a refresh time TR is longer than a measurement time TM, and FIG. 8B illustrates a waveform example in a case where TR>TM is satisfied. Similarly to FIGS. 7A and 7B, the amplitude of the waveform is changed between 0 V and a power voltage of a circuit in digital. For example, the refresh time TR and the measurement time TM may be freely set by a control circuit such as a microcomputer. Therefore, it is possible to suppress the drift according to a situation.

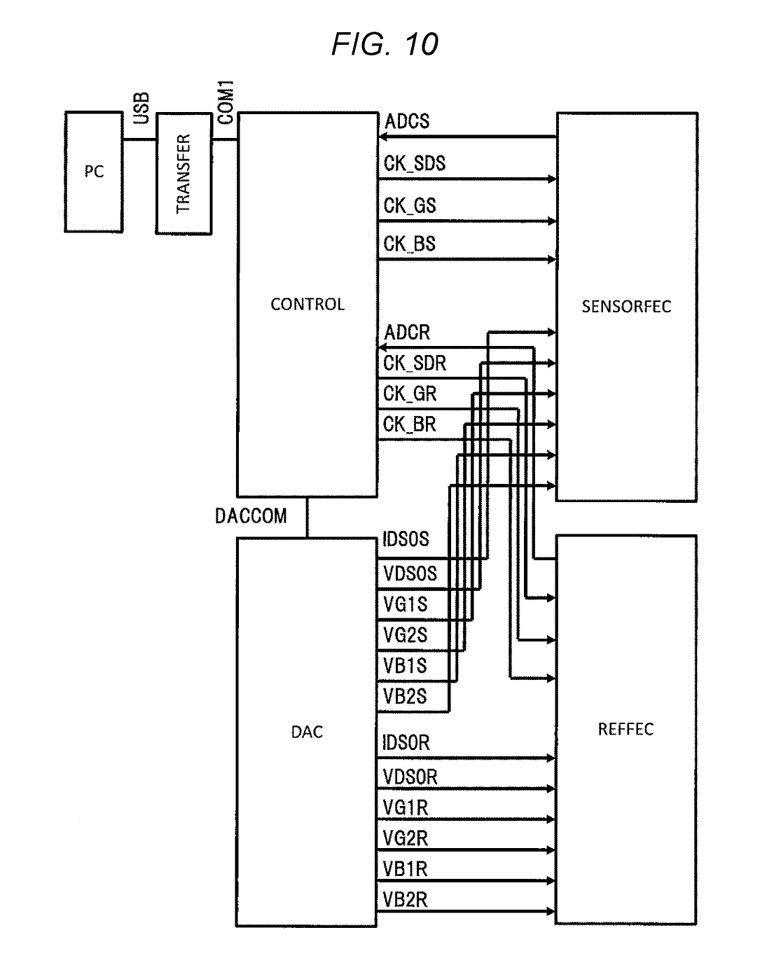

FIG. 10 is a diagram illustrating a configuration example of the entire system in the gas sensor according to the present example. A control circuit CONTROL such as a microcomputer and a control voltage source DAC are connected to a front end circuit SENSORFEC of a sensor FET and a front end circuit REFFEC of a reference FET, respectively. By communication DACCOM, the control circuit CONTROL controls the control voltage source DAC. A communication device TRANSFER and the control circuit are connected with each other through communication means COM1, and for example, the communication device and a PC perform communication through a USB. Therefore, a sensor output may be transmitted to the PC or the like after an appropriate operation is performed, and an output and additional processes are possible by the PC or the like. Naturally, it is possible to perform direct communication between the control circuit CONTROL and a PC or the like by removing a communication device (TRANSFER), and wireless communication may be performed. Communication means may be suitably selected according to demand of a system to which the gas sensor is applied.

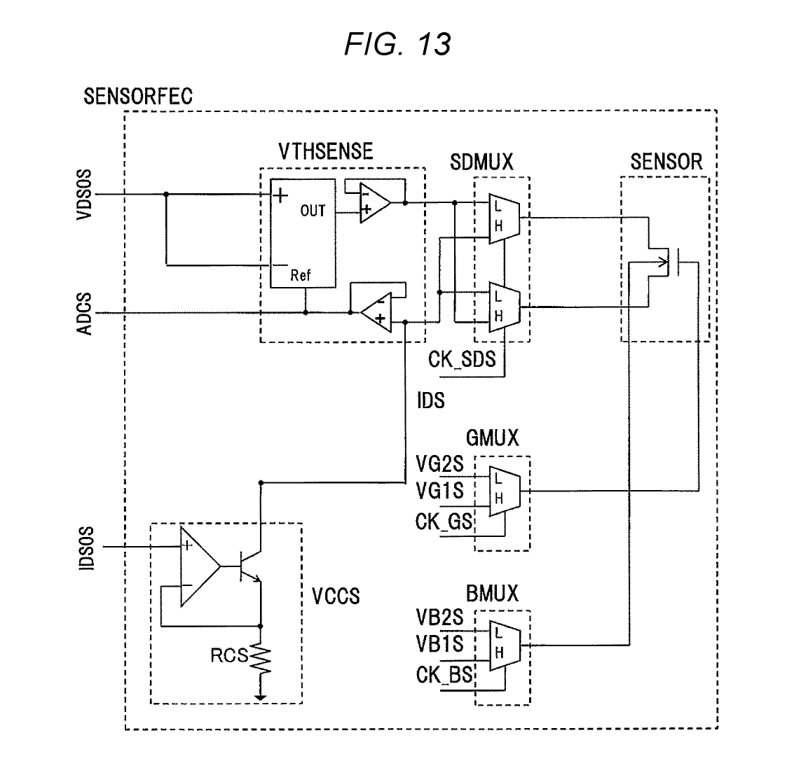

FIG. 13 illustrates an example of a specific configuration of the front end circuit of the sensor FET. For example, the front end circuit SENSORFEC of the sensor FET includes a VTH detection circuit VTHSENSE, a source-drain switch SDMUX, a sensor FET SENSOR, a first switch GMUX which changes a voltage which is applied to a gate electrode, a second switch BMUX which changes a voltage which is applied to a body electrode, a voltage control current source VCCS, and the like. In front of the VTH detection circuit VTHSENSE, an input low pass filter or a switch for switching a P channel FET dedicated input and an N channel FET dedicated input may be configured. It is possible to suppress an oscillation of an operational amplifier which is used in a driver, by configuring the input low pass filter. In addition, an output low pass filter may be provided between the source-drain switch SDMUX and the sensor FET SENSOR.

A sensor FET dedicated VDS setting potential VDSOS, a sensor FET dedicated IDS setting potential IDSOS, sensor FET dedicated gate potentials VG1S and VG2S, and sensor FET dedicated body potentials VB1S and VB2S are generated by the control voltage source DAC, and are applied to the sensor FET. Three kinds of clocks of a sensor FET dedicated source drain control clock CK_SDS, a sensor FET dedicated gate control clock CK_GS, and a sensor FET dedicated body control clock CK_BS are input to the front end circuit of the sensor FET from the control circuit. An output ADCS of the sensor FET is input to the control circuit. For example, the output ADCS of the sensor FET is input to an analog digital converter which is built in a microcomputer.

For example, the source-drain switch SDMUX is configured from two switches, and connects an H input terminal to an output terminal in a case where a clock input is H and connects an L input terminal to the output terminal in a case where the clock input is L. The source-drain switch SDMUX serves as a switch which combines signals of analog levels as they are.

For example, the first switch GMUX is configured from one switch. It is possible to apply a switch the same as that of the source-drain switch SDMUX to the first switch GMUX. Similarly, for example, the second switch BMUX is configured from one switch, and it is possible to apply a switch the same as that of the source-drain switch SDMUX to the second switch BMUX.

For example, the current control voltage source VCCS includes an operational amplifier, an NPN transistor, and a feedback resistor RCS. With respect to the sensor FET dedicated IDS setting potential IDSOS, an output current of IDSOS/RCS is generated. That is, it is possible to adjust the output current by the sensor FET dedicated IDS setting potential IDSOS.

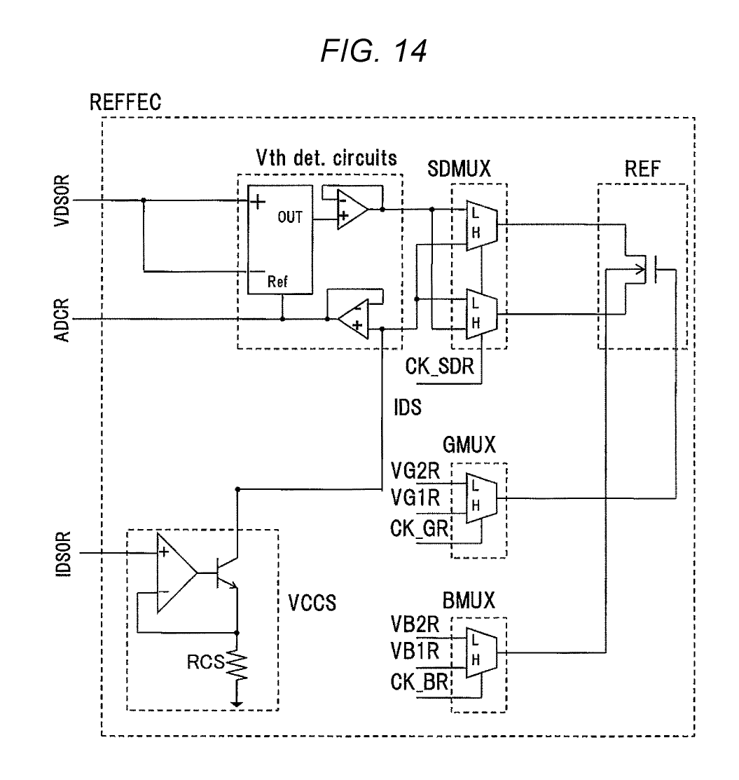

Next, a front end circuit REFFEC of the reference FET is described using FIG. 14. The circuit configuration is the same as that of the front end circuit of the sensor FET in FIG. 13, but inputs and outputs are different from each other.

A reference FET dedicated VDS setting potential VDSOR, a reference FET dedicated IDS setting potential IDSOR, reference FET dedicated gate potentials VG1R and VG2R, and reference FET dedicated body potentials VB1R and VB2R are generated by the control voltage source DAC, and are applied to the reference FET.

Three kinds of clocks of a reference FET dedicated source drain control clock CK_SDR, a reference FET dedicated gate control clock CK_GR, and a reference FET dedicated body control clock CK_BR are input to the front end circuit of the reference FET from the control circuit. An output ADCR of the reference FET is input to the control circuit. For example, the output ADCR of the reference FET is input to an analog digital converter which is built in a microcomputer.

### Modification Example Related to Setting Method of Each Parameter Used in Drift Suppression

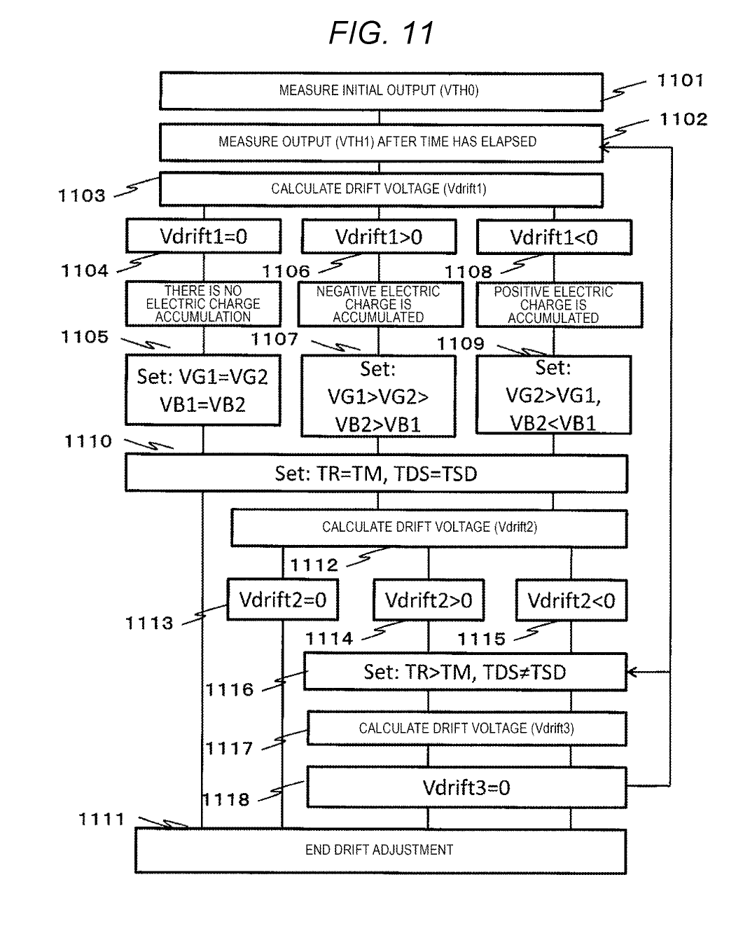

FIG. 11 illustrates an example of a flow showing a method of determining, the gate potentials VG1 and VG2, the body potentials VB1 and VB2, the refresh period TR, the measurement period TM, and the time TDS and TSD in which the current flows between the drain electrode and the source electrode, that are parameters used in the suppression of the drift, which are described above, by using a circuit. For example, such parameters are determined and stored in a memory at the time of a shipment adjustment of the gas sensor, and values thereof are used. In addition, FIG. 11 illustrates a setting method of a parameter of an N channel FET, and polarities of a VG and a VB are inverted in a P channel FET.

A shipment adjustment is performed in a state in which a detection target gas does not exist or sensitivity is less than detection sensitivity. First, an initial output VTH0 of a sensor is measured (1101). Next, an output VTH1 after a predetermined time has elapsed is measured (1102). Then, a drift voltage (Vdrift1=VTH1−VTH0) is obtained (1103). In an initial state, VG1=VG2 and VB1=VB2 are set. Here, in a case where Vdrift1=0 is satisfied (1104), since there is no drift, it is considered that there is no the accumulation of the electric charge, and a setting is not changed as VG1=VG2 and VB1=VB2 are satisfied (1105).

In a case where Vdrift1>0 is satisfied (1106), since a drift is performed in a direction in which an output is increased, it is considered that a negative electric charge is accumulated in the vicinity of a response gate. Therefore, voltages are set as VG1>VG2>VB2>VB1 is satisfied (1107). By setting the voltages as described above, in the refresh phase, the gate potential may be increased to be greater than the body potential. Therefore, it is possible to efficiently remove the accumulated negative electric charge from the gate electrode.

On the other hand, in a case where Vdrift1<0 is satisfied (1108), since the drift is performed in a direction in which the output is decreased, it is considered that a positive electric charge is accumulated in the vicinity of the response gate. Therefore, voltages are set as VG1<VG2 and VB2<VB1 are satisfied (1109). By setting the voltages as described above, in the refresh phase, the body potential may be increased to be greater than the gate potential. Therefore, it is possible to efficiently remove the accumulated positive electric charge from the gate electrode. In addition, a setting in which the gate potential and the body potential are inverted as VB1>VG2>VB2>VG1 is satisfied is also considered in a case where a value of the Vdrift1 is large.

Next, a duty of a clock is set to 50% as TR=TS and TDS=TSD are satisfied (1110), and in a case where Vdrift1=0 is satisfied, the adjustment is ended (1111).

In a case where Vdrift1≠0 is satisfied, in order to check the drift again, an output VTH2 after a predetermined time has elapsed is obtained, and a drift voltage (Vdrift2=VTH2−VTH0) is calculated (1112).

Here, in a case where Vdrift2≠0 is satisfied (1113), the adjustment is ended (1111). In a case where Vdrift2≠0 is satisfied (1114 and 1115), the clock duty is changed as TR>TM is satisfied (1116). This is because it is possible to increase possibility of the removal of the accumulated electric charge by setting the refresh period is to be longer than the measurement period. The duty ratios of the TDS and the TSD are suitably adjusted (1116˜1118) as Vdrift3=0 is satisfied, by the drift check (1117 and 1118) by an additional drift voltage measurement. In addition, in a case where Vdrift3≠0 is satisfied, it is considered that the VTH1 measurement is started again (1102) and a condition is searched.

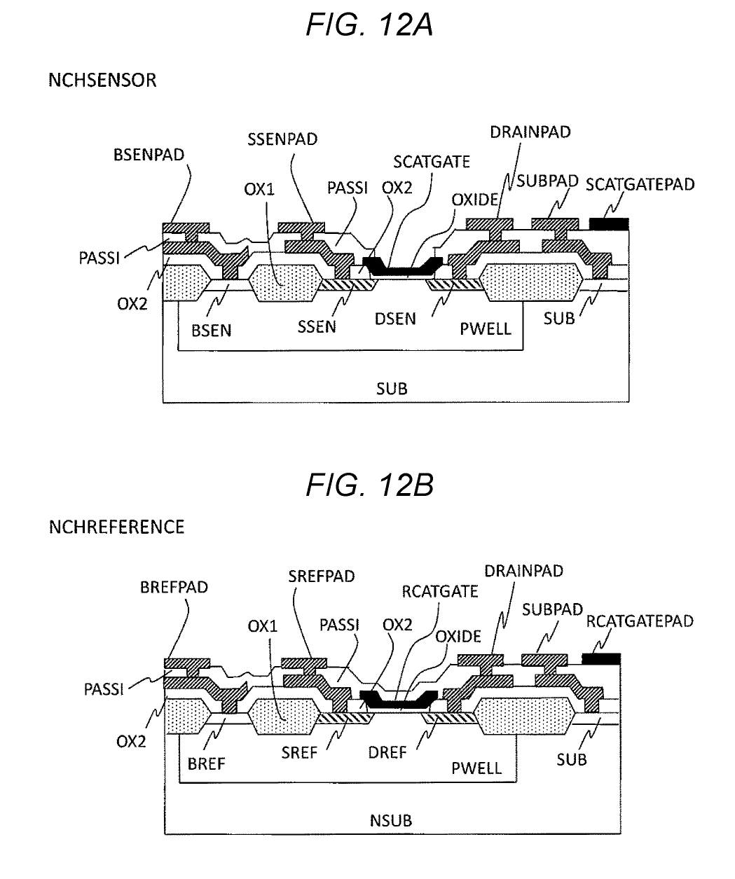

FIGS. 12A and 12B are an example of a sectional view of a structure in a case where a semiconductor element is formed of an N channel FET. A P type well PWELL is formed on a substrate SUB, and an N type FET is formed at the center of the P type well PWELL. Both of a sensor FET NCHSENSOR and a reference FET NCHREFERENCE include catalyst gate electrodes SCATGATE and RCATGATE. The catalyst gate electrode SCATGATE of the sensor FET is exposed by a through-hole which is formed through a barrier film PASSI. In contrast, the catalyst gate electrode RCATGATE of the reference FET is covered by the barrier film PASSI. A gate oxide film OXIDE is disposed under the catalyst gate electrode. In addition, an element separation film OX1 and an interlayer film OX2 are provided.

A drain terminal DREF of the reference FET is connected to a drain pad DRAINPAD, a source terminal SREF of the reference FET is connected to a source pad SREFPAD, a well terminal BREF of the reference FET is connected to a body pad BREFPAD, the catalyst gate electrode RCATGATE is connected to a gate pad RCATGATEPAD, and the substrate SUB is connected to a substrate potential pad SUBPAD, respectively. Therefore, it is possible to input and output a signal.

A drain terminal DSEN of the sensor FET is connected to the drain pad DRAINPAD, a source terminal SSEN of the sensor FET is connected to a source pad SSENPAD, a well terminal BSEN of the sensor FET is connected to a body pad BSENPAD, and the catalyst gate electrode SCATGATE is connected to a gate pad SCATGATEPAD, respectively. Therefore, it is possible to input and output a signal.

In addition, a sensor FET PCHSENSOR and a reference FET PCHREFERENCE are separately illustrated in FIGS. 12A and 12B for a comparison description, but in reality, the sensor FET PCHSENSOR and the reference FET PCHREFERENCE are formed on a common P type substrate PSUB.

What is claimed is:

1. A gas sensor that is a field effect transistor type, the gas sensor comprising:
a substrate;
an oxide film on the substrate;
a gate electrode on the oxide film;
a body electrode which is disposed on the substrate;
a first switch that changes a voltage which is applied to the gate electrode; and
a second switch that changes a voltage which is applied to the body electrode,
wherein the gate electrode and the first switch are connected with each other through an electrical wire.

2. The gas sensor according to claim 1, further comprising:
a voltage source that generates a plurality of voltages,
wherein the first switch switches a connection between the gas sensor and the plurality of voltages which are generated by the voltage source to change the voltage applied to the gate electrode.

3. The gas sensor according to claim 1, further comprising:
a voltage source that generates a plurality of voltages,
wherein the second switch switches a connection between the gas sensor and the plurality of voltages which are generated by the voltage source to change the voltage applied to the body electrode.

4. The gas sensor according to claim 1,
wherein a duty ratio and a phase are changeable by the first switch and the second switch, respectively,
the gas sensor further comprising:
a control unit that controls the first switch by a first clock and control the second switch by a second clock.

5. The gas sensor according to claim 1, further comprising:
a voltage source that generates a plurality of voltages,
wherein the first switch switches a connection between the gas sensor and the plurality of voltages which are generated by the voltage source to change the voltage applied to the gate electrode, and
the second switch switches the connection between the gas sensor and the plurality of voltages which are generated by the voltage source to change the voltage applied to the body electrode.

6. The gas sensor according to claim 1, further comprising:
a source electrode and a drain electrode which are disposed on the substrate;
a voltage source that generates a plurality of voltages;
a current source that generates a plurality of currents; and
a source-drain switch that changes a direction of a current flowing to the source electrode and the drain electrode.

7. The gas sensor according to claim 6,
wherein the source-drain switch switches a connection between a first source terminal of the source electrode and the voltage source, a connection between a first drain terminal of the drain electrode and the current source, a connection between a second drain terminal of the drain electrode and the voltage source, and a connection between a second source terminal of the source electrode and the current source, to change the direction of the current flowing to the source electrode and the drain electrode.

8. The gas sensor according to claim 5,
wherein the first switch applies a first voltage to the gate electrode during a measurement period and applies a second voltage to the gate electrode during a refresh period,
the second switch applies a third voltage to the body electrode during the measurement period and applies a fourth voltage to the body electrode during the refresh period, and
the second voltage is greater than the first voltage, the first voltage is greater than the third voltage, and the third voltage is greater than the fourth voltage.

9. The gas sensor according to claim 5,
wherein the first switch applies a first voltage to the gate electrode during a measurement period and applies a second voltage to the gate electrode during a refresh period,
the second switch applies a third voltage to the body electrode during the measurement period and applies a fourth voltage to the body electrode during the refresh period, and
the first voltage is greater than the second voltage, and the fourth voltage is greater than the third voltage.

10. The gas sensor according to claim 1,
wherein a gas of a measurement target is hydrogen.

11. A method of setting a control value of a gas sensor that is a field effect transistor type, the gas sensor including a substrate, an oxide film on the substrate, a gate electrode on the oxide film, and a body electrode which is disposed on the substrate, the method comprising:
measuring a drift voltage which is a change of an output after a predetermined time of the gas sensor elapses, in a state where a concentration of a gas which is a measurement target of the gas sensor is less than a predetermined detection sensitivity; and
setting a gate voltage which is applied to the gate electrode and a body voltage which is applied to the body electrode, based on a value of the measured drift voltage.

12. The method of setting a control value of a gas sensor according to claim 11, further comprising:
setting a duty ratio of a clock which is for controlling a first switch that changes the gate voltage and a second switch that changes the body voltage, based on a value of the measured drift voltage.
